(19) United States
(12) Patent Application Publication
(10) Pub. No.: US 2025/0374812 A1
(43) Pub. Date: Dec. 4, 2025

(54) DISPLAY PANEL AND FABRICATION METHOD THEREOF, AND DISPLAY DEVICE

(71) Applicants: Wuhan Tianma MicroElectronics Co., Ltd. Shanghai Branch, Shanghai (CN); Wuhan Tianma Micro-Electronics Co., Ltd., Shanghai (CN)

(72) Inventor: Biming WEI, Shanghai (CN)

(21) Appl. No.: 18/952,593

(22) Filed: Nov. 19, 2024

(30) Foreign Application Priority Data
May 29, 2024 (CN) 202410688580.1

(51) Int. Cl. H10K 59/80; H10K 59/12; H10K 59/40

(52) U.S. Cl. CPC H10K 59/8792; H10K 59/1201; H10K 59/873; H10K 59/40

(57) ABSTRACT

A display panel, a fabrication method of a display panel, and a display device are provided. The display panel includes: an array substrate; a thin film encapsulation layer including an organic encapsulation layer and located on a light-emitting side of the array substrate; a cover plate located on a side of the thin film encapsulation layer away from the array substrate; and a light shielding layer at an edge climbing position of the organic encapsulation layer. The light shielding layer is disposed between the organic encapsulation layer and the cover plate.

### CROSS-REFERENCE TO RELATED APPLICATION

This application claims the priority of Chinese Patent Application No. 202410688580.1, filed on May 29, 2024, the content of which is incorporated herein by reference in its entirety.

### TECHNICAL FIELD

The present disclosure generally relates to the field of display technologies and, more particularly, relates to a display panel, a fabrication method of a display panel, and a display device.

### BACKGROUND

At present, when preparing and forming a thin film encapsulation layer for a flexible encapsulation electronic product, an organic encapsulation layer in the thin film encapsulation layer has an edge climbing position, which causes a curvature area corresponding to the edge climbing position of the thin film encapsulation layer. When the light from the display area is emitted to the curvature area of the thin film encapsulation layer, the emitted light with a small angle at an arc edge is stronger, and the stronger emitted light is reflected and refracted when passing through a cover plate, causing the emitted light to leak in the edge area and converge to form an aperture.

### SUMMARY

One aspect of the present disclosure provides a display panel. The display panel includes: an array substrate; a thin film encapsulation layer including an organic encapsulation layer and located on a light-emitting side of the array substrate; a cover plate located on a side of the thin film encapsulation layer away from the array substrate; and a light shielding layer at an edge climbing position of the organic encapsulation layer. The light shielding layer is disposed between the organic encapsulation layer and the cover plate.

Another aspect of the present disclosure provides a fabrication method of a display pane. The method includes: forming an array substrate; forming a thin film encapsulation layer on a light-emitting side of the array substrate; forming a light shielding layer above an edge climbing position of an organic encapsulation layer of the thin film encapsulation layer; and providing a cover plate arranged on a light-emitting side of the organic encapsulation layer.

Another aspect of the present disclosure provides a display device including a display panel. The display panel includes: an array substrate; a thin film encapsulation layer including an organic encapsulation layer and located on a light-emitting side of the array substrate; a cover plate located on a side of the thin film encapsulation layer away from the array substrate; and a light shielding layer at an edge climbing position of the organic encapsulation layer. The light shielding layer is disposed between the organic encapsulation layer and the cover plate.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a film layer structure of a display panel.

FIG. 2 illustrates a film layer structure of an exemplary display panel consistent with various disclosed embodiments of the present disclosure.

FIG. 3 illustrates a film layer structure of another exemplary display panel consistent with various disclosed embodiments of the present disclosure.

FIG. 4 illustrates a film layer structure of another exemplary display panel consistent with various disclosed embodiments of the present disclosure.

FIG. 5 illustrates a film layer structure of another exemplary display panel consistent with various disclosed embodiments of the present disclosure.

FIG. 6 illustrates a film layer structure of another exemplary display panel consistent with various disclosed embodiments of the present disclosure.

FIG. 7 illustrates a film layer structure of another exemplary display panel consistent with various disclosed embodiments of the present disclosure.

FIG. 8 illustrates a film layer structure of another exemplary display panel consistent with various disclosed embodiments of the present disclosure.

FIG. 9 illustrates a top view of a light locking layer at an edge climbing position of an exemplary display panel consistent with various disclosed embodiments of the present disclosure.

FIG. 10 illustrates a film layer structure of another exemplary display panel consistent with various disclosed embodiments of the present disclosure.

FIG. 11 illustrates a film layer structure of another exemplary display panel consistent with various disclosed embodiments of the present disclosure.

FIG. 12 illustrates an exemplary display device consistent with various disclosed embodiments of the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

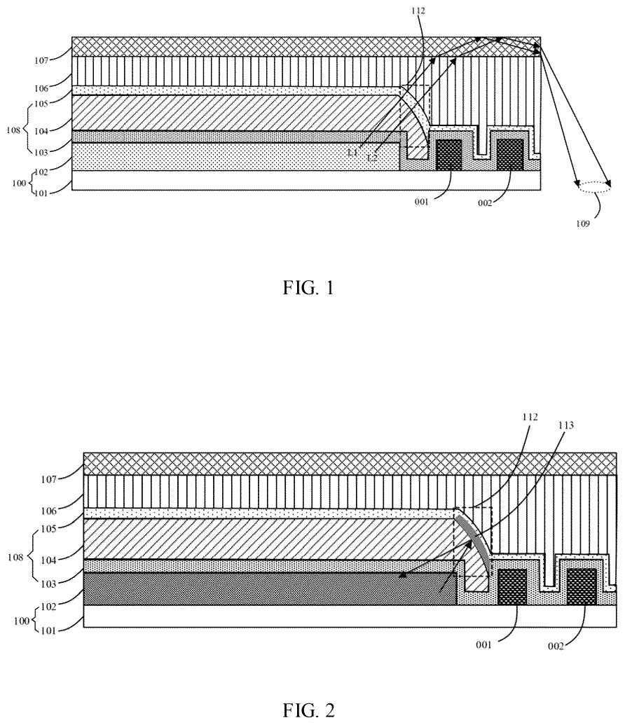

FIG. 1 shows a film layer structure of a display panel in existing technology. As shown in FIG. 1, the display panel includes an array substrate 100, a thin film encapsulation layer 108 and a cover plate 107.

The thin film encapsulation layer 108 covers a light-emitting side of the array substrate 100 and is used to encapsulate the array substrate 100. The cover plate 107 is located on a side of the thin film encapsulation layer 108 away from the array substrate 100. The array substrate 100 includes a substrate 101 and a multifunctional layer 102 disposed on the substrate 101. The multifunctional layer 102 includes a driving circuit layer, an anode layer, an organic light-emitting layer, and a cathode layer, etc. stacked together, which are not limited here.

The thin film encapsulation layer 108 includes a first inorganic encapsulation layer 103, an organic encapsulation layer 104, and a second inorganic encapsulation layer 105 stacked and covered on the light-emitting side of the array substrate 100 in sequence. The first inorganic encapsulation layer 103 (CVD1) may be formed by a chemical vapor deposition process. The organic encapsulation layer 104 (IJP) may be formed by an inkjet printing process, and the second inorganic encapsulation layer 105 (CVD2) may be formed by a chemical vapor deposition process. Therefore, the display panel shown in FIG. 1 adopts a CVD1-IJP-CVD2 three-layer encapsulation structure to form the thin film encapsulation layer 108.

The display panel also includes an adhesive layer 106, and the cover plate 107 is covered on the light-emitting side of the array substrate 100 through the adhesive layer 106. The material of the cover plate 107 may be glass or transparent resin (Colorless Polyimide, CPI) and the like.

It should be noted that the display panel may also include other functional layers not shown in FIG. 1, such as but not limited to a polarizer, and the polarizers may be arranged between the thin film encapsulation layer 108 and the cover plate 107.

During the encapsulation process of the thin film encapsulation layer 108, since the organic encapsulation layer 105 is in a liquid state before curing, the organic encapsulation layer 105 has a large fluidity and it is difficult to accurately control diffusion of the organic encapsulation layer 105. Therefore, the organic encapsulation layer 105 is easy to flow out. A first retaining wall structure 001 and a second retaining wall structure 002 are provided in FIG. 1 to prevent the organic encapsulation layer 105 from flowing out before curing and ensure that the second inorganic encapsulation layer 105 effectively wraps the organic encapsulation layer 104. Therefore, water and oxygen in the external environment are prevented from easily entering the interior of the display device, corroding the organic light-emitting layer, and causing the problem of displaying black spots.

As shown in FIG. 1, the organic encapsulation layer 104 has an edge climbing position 112 during the formation process, such that the thin film encapsulation layer 108 formed by the organic encapsulation layer 104 has a curvature region corresponding to the edge climbing position 112. When the light of the display area 110 (an organic light-emitting layer in the multifunctional layer 102 emitting light) is emitted to the curvature region, the light emitted at a small angle of curvature edges is strong. The strong light is reflected and refracted when passing through the cover plate 107 (as shown in the light path schematic diagram of FIG. 1), causing the light to leak in the edge areas of the display panel and converge to form an aperture 109.

Exemplarily, as shown in FIG. 1, when the first light L1 and the second light L2 emitted by the organic light-emitting layer in the multifunctional layer 102 pass through the edge climbing position 112 and reach the cover plate 107, refraction, total reflection or refraction occur on the cover plate 107 in sequence, causing the first light L1 and the second light L2 to leak in the edge area and converge to form the aperture 109.

The present disclosure provides a display panel to at least partially alleviate the above problems. In the display panel provided by the present disclosure, corresponding to the edge climbing position of the organic encapsulation layer, a light shielding layer may be arranged between the organic encapsulation layer and the cover plate. When the light from the display area is emitted to the edge climbing position of the organic encapsulation layer, the light shielding layer arranged at the edge climbing position may block the light emitted from the display area to the edge climbing position, thereby improving the problem of light leakage when the light from the display area is emitted to the edge area.

The present disclosure provides a display panel. FIG. 2 shows a film layer structure of an exemplary display panel provided by the present disclosure. As shown in FIG. 2, in one embodiment, the display panel may include an array substrate 100, a thin film encapsulation layer 108, a cover plate 107 and a light shielding layer 113.

In one embodiment, the display panel may be an organic light-emitting diode (OLED) display panel, which is used to display images when working. The display panel may include a display area and a non-display area, and the non-display area may be arranged around the display area, which is not limited here.

The array substrate 100 may include a substrate 101 such as a flexible substrate 101 and a multifunctional layer 102 arranged on the substrate 101. The multifunctional layer 102 may include a driving circuit layer, an anode layer, an organic light-emitting layer and a cathode layer, etc., stacked together and which are not limited here.

The thin film encapsulation layer 108 may be located on a light-emitting side of the array substrate 100 to realize the encapsulation of the array substrate 100. The thin film encapsulation layer 108 may include a first inorganic encapsulation layer 103, an organic encapsulation layer 104 and a second inorganic encapsulation layer 105 stacked in sequence. The cover plate 107 may be located on a side of the thin film encapsulation layer 108 facing away from the array substrate 100. Exemplarily, in one embodiment, the cover plate 107 may be covered on the upper surface of the thin film encapsulation layer 108 through the adhesive layer 106.

Corresponding to an edge climbing position 112 of the organic encapsulation layer 104, the light shielding layer 113 may be provided between the organic encapsulation layer 104 and the cover plate 107. Exemplarily, in one embodiment shown in FIG. 2, the light shielding layer 113 may be provided at the edge climbing position 112 on the upper surface of the organic encapsulation layer 104. When the light of the display area is emitted to the edge climbing position 112, the light shielding layer 113 provided at the edge climbing position 112 of the organic encapsulation layer 104 may block the light emitted from the display area to the edge climbing position 112, such that the light of the display area is not able to be incident on the cover plate 107 when it is emitted to the edge climbing position 112. Therefore, emission and refraction of the light incident on the cover plate 107 may be prevented, thereby improving the problem of light leakage in FIG. 1 because of the light of the display area being emitted to the edge area.

In the display panel provided by the present disclosure, the display panel may include the array substrate, the thin film encapsulation layer located on the light-emitting side of the array substrate and including the organic encapsulation layer, and the cover plate located on the side of the thin film encapsulation layer away from the array substrate. The light shielding layer may be provided at the edge climbing position of the organic encapsulation layer, and the light shielding layer may be located between the organic encapsulation layer and the cover plate. Corresponding to the edge climbing position of the organic encapsulation layer, the light shielding layer may be arranged between the organic encapsulation layer and the cover plate. When the light from the display area is emitted to the edge climbing position of the organic encapsulation layer, the light shielding layer arranged at the edge climbing position may block the light emitted from the display area to the edge climbing position, thereby improving the problem of light leakage when the light from the display area is emitted to the edge area.

In one embodiment shown in FIG. 2, the light shielding layer 113 at the edge climbing position 112 of the organic encapsulation layer 104 may be formed by, for example, a photolithography process or a spraying process.

In some other embodiments, the light shielding layer 113 at the edge climbing position 112 of the organic encapsulation layer 104 may be formed by other processes well known to those skilled in the art, which is not limited or repeated in the present disclosure.

In some embodiments, as shown in FIG. 2, the light shielding layer 113 may be specifically arranged at the edge climbing position 112 of the upper surface of the organic encapsulation layer 104. By arranging the light shielding layer 113 at the edge climbing position 112 of the upper surface of the organic encapsulation layer 104, it may be possible to arrange the light shielding layer 113 between the organic encapsulation layer 104 and the cover plate 107, thereby blocking the light transmission path between the edge climbing position 112 of the organic encapsulation layer 104 and the cover plate 107.

In one embodiment, after the first inorganic encapsulation layer 103 and the organic encapsulation layer 104 are sequentially formed on the array substrate 100, the light shielding layer 113 may be formed by a photolithography process or a spraying process at the edge climbing position 112 of the upper surface of the organic encapsulation layer 104, and then the second inorganic encapsulation layer 105 may be formed.

Therefore, the light shielding layer 113 may be arranged at the edge climbing position 112 of the upper surface of the organic encapsulation layer 104. When the light of the display area is emitted to the edge climbing position 112, the light of the display area emitted to the edge climbing position 112 may be blocked by the light shielding layer 113 arranged at the edge climbing position 112.

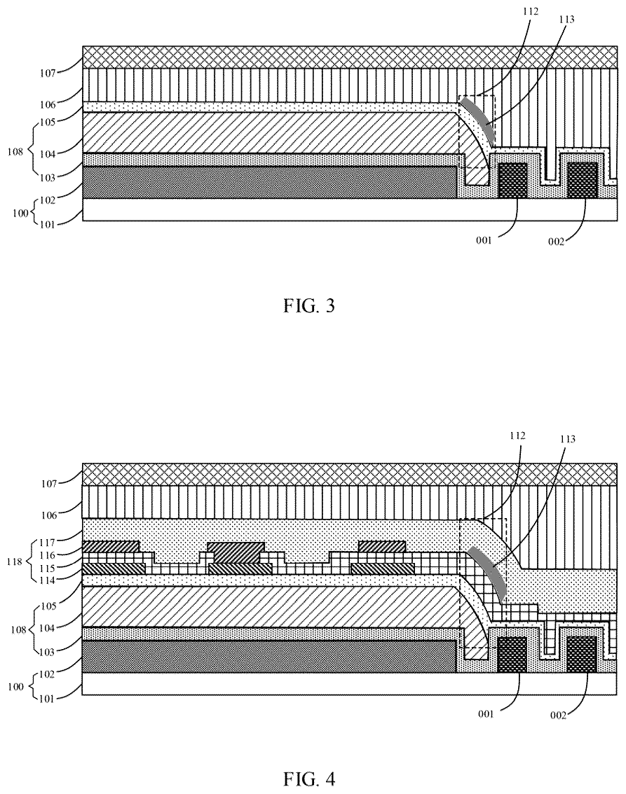

In some other embodiments shown in FIG. 3 illustrating a film layer structure of another exemplary display panel, the light shielding layer 113 may be disposed at the edge climbing position 112 of the top layer of the thin film encapsulation layer 108. By disposing the light shielding layer 113 at the edge climbing position 112 of the top layer of the thin film encapsulation layer 108, it may be possible to dispose the light shielding layer 113 between the organic encapsulation layer 104 and the cover plate 107, thereby blocking the light transmission path between the edge climbing position 112 of the organic encapsulation layer 104 and the cover plate 107.

In one embodiment, after the thin film encapsulation layer 108 is formed on the light-emitting side of the array substrate 100, the light shielding layer 113 may be disposed at the top layer of the thin film encapsulation layer 108 corresponding to the edge climbing position 112, that is, the light shielding layer 113 may be disposed at the upper surface of the thin film encapsulation layer 108, for example, at the surface of the second inorganic encapsulation layer 105 corresponding to the edge climbing position 112.

By setting the light shielding layer 113 at the edge climbing position 112 of the top layer of the thin film encapsulation layer 108, when the light from the display area is emitted to the edge climbing position 112, the light shielding layer 113 set at the edge climbing position 112 may block the light emitted from the display area to the edge climbing position 112.

In some other embodiments shown in FIG. 4 illustrating a film layer structure of another exemplary display panel, the display panel may further include a touch structure layer 118. The touch structure layer 118 may be located between the thin film encapsulation layer 108 and the cover plate 107. The light shielding layer 113 may be located on the surface of any film layer of the touch structure layer 118 away from the thin film encapsulation layer 108, and may be arranged at the edge climbing position 112. By using the touch structure layer 118 arranged between the thin film encapsulation layer 108 and the cover plate 107, and arranging the light shielding layer 113 on the surface of any film layer of the touch structure layer 118 away from the thin film encapsulation layer 108 and corresponding to the edge climbing position 112, it may be also possible to arrange the light shielding layer 113 between the organic encapsulation layer 104 and the cover plate 107, thereby blocking the light transmission path between the edge climbing position 112 of the organic encapsulation layer 104 and the cover plate 107.

As shown in FIG. 4, after the thin film encapsulation layer 108 is prepared on the array substrate 100, the touch structure layer 118 may be prepared on the thin film encapsulation layer 108. The touch structure layer 118 may include multiple film layers.

As shown in FIG. 4, the touch structure layer 118 may include a first touch metal layer 114, a first insulating layer 115, a second touch metal layer 116, and a second insulating layer 117. For example, the first touch metal layer 114 may be used to set touch leads, and the second touch metal layer 116 may be used to set touch electrodes.

As shown in FIG. 4, in one embodiment, corresponding to the edge climbing position 112, the touch structure layer 118 may include the first insulating layer 115 and the second insulating layer 117 stacked in sequence. As shown in FIG. 4, for example, the light shielding layer 113 may be set on any film layer of the touch structure layer 118, such as the surface of the first insulating layer 115. That is, the light shielding layer 113 may be set on the surface of the first insulating layer 115 away from the thin film encapsulation layer 108, that is, the light shielding layer 113 may be set on the upper surface of the first insulating layer 115, and the light shielding layer 113 may be set corresponding to the edge climbing position 112. By setting the light shielding layer 113 on the upper surface of the edge climbing position 112 of the first insulating layer 115, when the light of the display area is emitted to the edge climbing position 112, the light shielding layer 113 set at the edge climbing position 112 may block the light emitted from the display area to the edge climbing position 112.

In some other embodiments shown in FIG. 4 illustrating a film layer structure of another exemplary display panel, the touch structure layer 118 may include a first touch metal layer 114, a first insulating layer 115, a second touch metal layer 116, and a second insulating layer 117. The light shielding layer 113 may be disposed on any film layer in the touch structure layer 118, such as the surface of the second insulating layer 117 away from the thin film encapsulation layer 108. That is, the light shielding layer 113 may be disposed on the upper surface of the second insulating layer 117, and the light shielding layer 113 may be arranged corresponding to the edge climbing position 112.

By disposing the light shielding layer 113 on the upper surface of the edge climbing position 112 of the second insulating layer 117, when the light from the display area is emitted through the edge climbing position 112, the light from the display area to the edge climbing position 112 may be blocked by the light shielding layer 113 disposed at the edge climbing position 112.

Therefore, the touch structure layer 118 disposed between the thin film encapsulation layer 108 and the cover plate 107 may be used to set the light shielding layer 113 on the surface of any film layer of the touch structure layer 118 away from the thin film encapsulation layer 108 and corresponding to the edge climbing position 112, such that the light shielding layer 113 may be disposed between the organic encapsulation layer 104 and the cover plate 107 to block the light transmission path between the edge climbing position 112 of the organic encapsulation layer 104 and the cover plate 107. When the light of the display area is emitted to the edge climbing position 112, the light shielding layer 113 disposed at the edge climbing position 112 may block the light emitted from the display area to the edge climbing position 112.

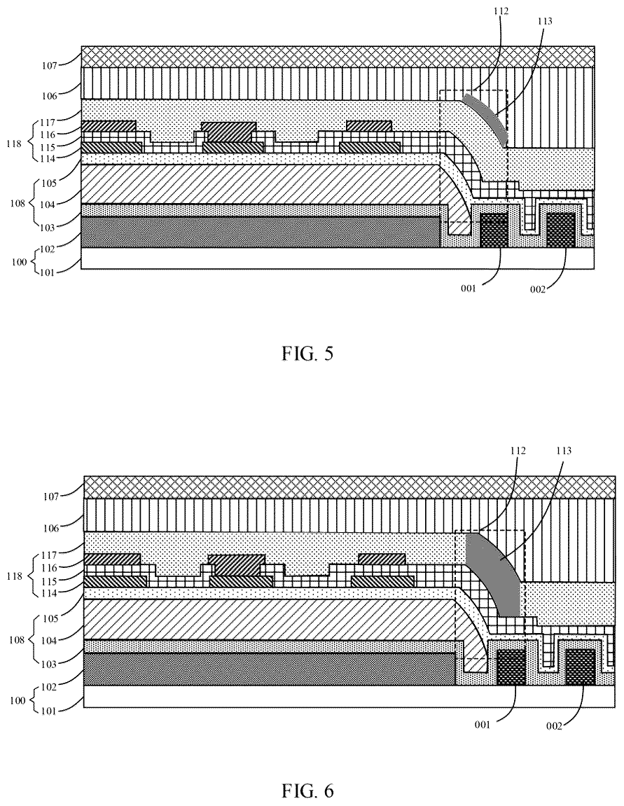

In the embodiments shown in FIG. 5, the display panel may include the touch structure layer 118, and the touch structure layer 118 may be located between the thin film encapsulation layer 108 and the cover plate 107. The light shielding layer 113 may be disposed on the surface of the touch structure layer 118 away from the thin film encapsulation layer 108, and may be arranged at the edge climbing position 112.

By disposing the light shielding layer 113 on the surface of the touch structure layer 118 away from the thin film encapsulation layer 108, the light shielding layer 113 may be arranged on the upper surface of the touch structure layer 118. In this embodiment, the light shielding layer 113 may be arranged after the preparation process of the touch structure layer 118 is completed, which will not affect the preparation process of the touch structure layer 118, for example, will avoid the preparation process of the light shielding layer from damaging the touch structure layer or introducing impurities.

Exemplarily, as shown in FIG. 5, the touch structure layer 118 may include the first touch metal layer 114, the first insulating layer 115, the second touch metal layer 116 and the second insulating layer 117. The second insulating layer 117 may be a surface film layer of the touch structure layer 118, and the light shielding layer 113 may be arranged on the upper surface of the second insulating layer 117, that is, the light shielding layer 113 may be arranged on the upper surface of the touch structure layer 118, and the light shielding layer 113 may be arranged corresponding to the edge climbing position 112.

In the present embodiment, when the display panel includes the touch structure layer 118 located between the thin film encapsulation layer 108 and the cover plate 107, the light shielding layer 113 may be arranged on the surface of the touch structure layer 118 away from the thin film encapsulation layer 108, that is, on the upper surface of the touch structure layer 118, and corresponding to the edge climbing position 112. When the light of the display area is emitted to the edge climbing position 112, the light of the display area emitted to the edge climbing position 112 may be blocked by the light shielding layer 113 arranged at the edge climbing position 112.

In the present disclosure, the light shielding layer 113 may be formed after the organic encapsulation layer 104 is formed on the array substrate 100. For example, the light shielding layer 113 may be disposed on the surface of the organic encapsulation layer 104 after the organic encapsulation layer 104 is formed on the array substrate 100. For another example, the light shielding layer 113 may be disposed on the surface of the thin film encapsulation layer 108 after the thin film encapsulation layer 108 is formed on the array substrate 100. For another example, the light shielding layer 113 may be disposed on the surface of any film layer of the touch structure layer 118 that is away from the thin film encapsulation layer 108 when the touch structure layer 118 is formed on the thin film encapsulation layer 108.

The preferred implementation of the disclosed embodiment is to provide the light shielding layer 113 after forming the thin film encapsulation layer 108 on the light-emitting side of the array substrate 100. For example, the light shielding layer 113 may be provided on the surface of the thin film encapsulation layer 108; or when preparing the touch structure layer 118 on the surface of the thin film encapsulation layer 108, the light shielding layer 113 may be provided on the touch structure layer 118.

In some embodiments shown in FIG. 2 to FIG. 5, a thickness of the light shielding layer 113 may be less than 30 microns. By setting the thickness of the light shielding layer 113 to be less than 30 microns, the problem of too large fluctuations on the surface of the film layer in the display panel caused by setting the thickness of the light shielding layer 113 too thick may be avoided.

In some other embodiments shown in FIG. 6 illustrating a film layer structure of another exemplary display panel, a touch structure layer 118 may be provided between the thin film encapsulation layer 108 and the cover plate 107. The touch structure layer 118 may include an insulating layer, and the insulating layer (such as the second insulating layer 117 shown in FIG. 6) may be provided with an opening at the edge climbing position 112 of the thin film encapsulation layer 108. The light shielding layer 113 may be disposed in the opening.

In the present embodiment, the light shielding layer 113 may be provided at the position of the opening of the insulating layer at the edge climbing position 112 of the thin film encapsulation layer. By providing the opening in the insulating layer at the edge climbing position 112 of the thin film encapsulation layer 108 and providing the light shielding layer 113 in the opening, it may be also possible to provide the light shielding layer 113 between the organic encapsulation layer 104 and the cover plate 107, thereby blocking the light transmission path between the edge climbing position 112 of the organic encapsulation layer 104 and the cover plate 107.

Exemplarily, in one embodiment as shown in FIG. 6, the touch structure layer 118 may include a first touch metal layer 114, a first insulating layer 115, a second touch metal layer 116 and a second insulating layer 117. An opening may be provided in the second insulating layer 117 at the edge climbing position 112 of the thin film encapsulation layer 108, and the light shielding layer 113 may be provided in the opening.

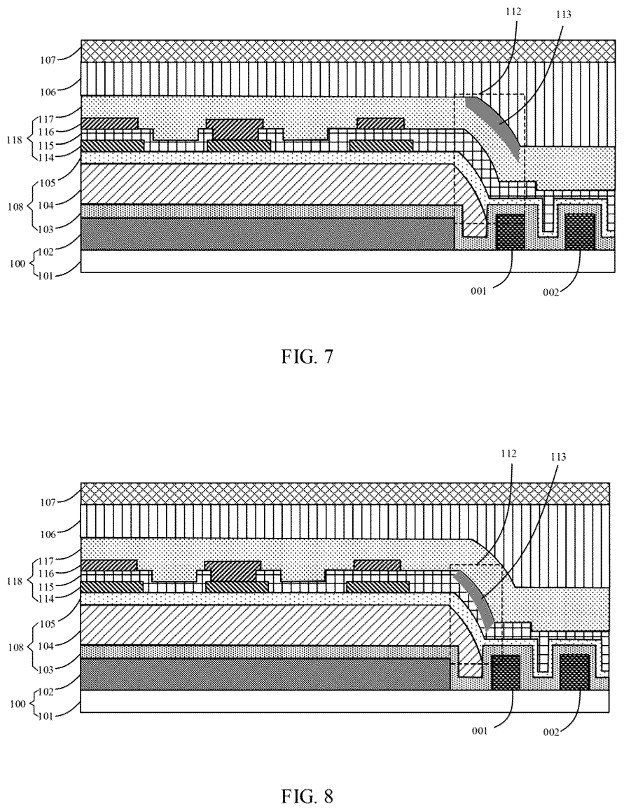

In some other embodiments shown in FIG. 7 illustrating a film layer structure of another exemplary display panel, the touch structure layer 118 may include a first touch metal layer 114, a first insulating layer 115, a second touch metal layer 116, and a second insulating layer 117. An opening may be provided in the second insulating layer 117 at the edge climbing position 112 of the thin film encapsulation layer 108, and the light shielding layer 113 may be provided in the opening. The difference between FIG. 6 and FIG. 7 is that the depth of the opening provided on the second insulating layer 117 is different. The depth of the opening on the insulating layer shown in FIG. 6 is larger than the depth of the opening on the insulating layer shown in FIG. 7, such that corresponding light shielding layers 113 are provided for different opening depths. FIG. 6 and FIG. 7 only exemplarily show two different opening depths, and the embodiments of the present disclosure are not limited thereto.

In some embodiments shown in FIG. 6 and FIG. 7, a side surface of the light shielding layer 13 away from the thin film encapsulation layer 108 may be flush with a side surface of the touch structure layer 118 away from the thin film encapsulation layer 108.

As shown in FIG. 6 or FIG. 7, the opening may be provided in the second insulating layer 117 and the light shielding layer 113 may be disposed in the opening. The side surface of the light shielding layer 113 away from the thin film encapsulation layer 108 may be flush with the side surface of the touch structure layer 118 away from the thin film encapsulation layer 108, to make sure that the upper surface of the light shielding layer 113 is flush with the surface of the second insulating layer 117. That is, the upper surface of the light shielding layer 113 may be flush with the upper surface of the touch structure layer 118, to avoid surface steps.

The upper surface of the light shielding layer 113 being flush with the upper surface of the touch structure layer 118 may be that the light shielding layer 113 fills the space in the opening and the volume of the light shielding layer 113 filled is equal to the capacity of the opening.

In some other embodiments shown in FIG. 8 illustrating a film layer structure of another exemplary display panel, the touch structure layer 118 may include a first touch metal layer 114, a first insulating layer 115, a second touch metal layer 116, and a second insulating layer 117. An opening may be provided at a position in the first insulating layer 115 corresponding to the edge climbing position 112 of the thin film encapsulation layer 108, and the light shielding layer 113 may be provided in the opening.

In some other embodiments, a touch structure layer may be further provided between the thin film encapsulation layer and the cover plate. The light shielding layer may be provided on the side of the touch structure layer away from the cover plate. A groove structure may be provided on the light shielding layer, and touch leads of the touch structure layer may be provided in the groove structure.

By utilizing the light shielding layer provided at the edge climbing position, the groove structure may be provided on the light shielding layer, and the touch leads may be provided in the groove structure. Therefore, the touch leads may not need to climb through the upper surface of the light shielding layer, thereby avoiding the problem of the touch leads breaking when the touch leads climb through the upper surface of the light shielding layer.

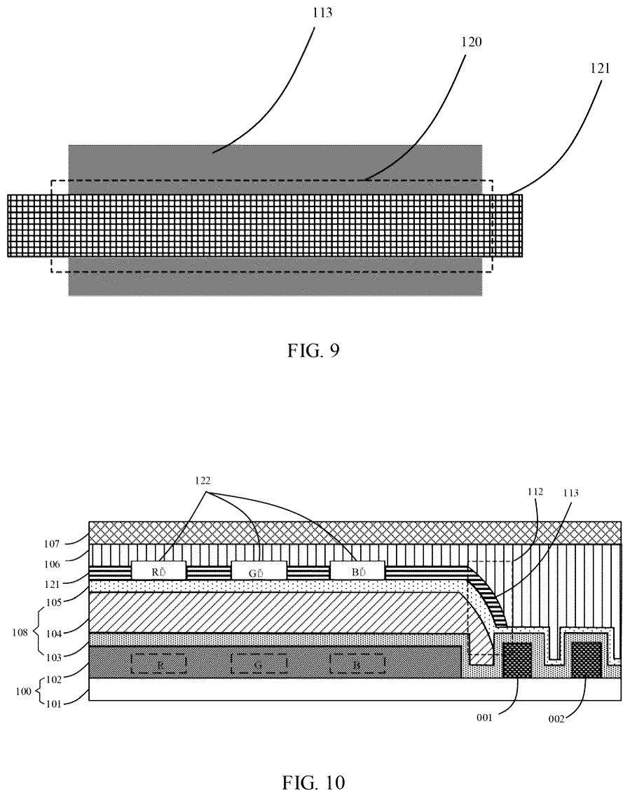

FIG. 9 is a top view of a light shielding layer at an edge climbing position provided by one embodiment of the present disclosure. As shown in FIG. 9, a groove structure 120 may be provided on the light shielding layer 113, and touch leads 121 may be disposed in the groove structure 120 and extend out of the groove structure 120.

In some embodiments, the display panel may include multiple metal film layers, and the ambient light irradiating the display panel may cause emission, which affects the user experience. Therefore, a polarizer is usually provided in the display panel to eliminate light reflection. However, setting a polarizer on the display screen requires increasing the process, and the thickness of the display panel after packaging is relatively thick, which is not conducive to thinness. Therefore, a CFOT (Color Filter On Touch) technology (depolarization technology) is used to replace the polarizer in the display panel to achieve the effect of eliminating light reflection.

Taking the OLED display panel as an example, when using the CFOT technology, color blocking structures of corresponding colors such as CF (Color Filters) may be formed in the light-emitting pixel area of the display panel, and a black BM (Black Matrix) may be formed in gaps between each pixel unit, which may prevent reflected light and improve transmittance. There may be no need to set a polarizer, reduce the process, and thus reduce the thickness of the display panel. Therefore, the CFOT technology may be used to replace the original polarizer to eliminate light reflection.

Based on the above-mentioned CFOT technology, the display panel may adopt the CFOT technology instead of the filter, to realize the reflection of external light through the color blocking layer. FIG. 10 is a schematic diagram of the film layer structure of another display panel provided by the present disclosure. As shown in FIG. 10, in some embodiments, the display panel may also include a color blocking structure array 122, and the color blocking structure array 122 may be arranged between the thin film encapsulation layer 108 and the cover plate 107. A black matrix 121 may be disposed between adjacent color blocking structures (such as red color blockers R′, green color blockers G′ or blue color blockers B′) of the color blocking structure array 122. The black matrix 121 may extend to the edge climbing position 12 of the organic encapsulation layer 104 to form the light shielding layer.

In this embodiment, the color blocking structure array 122 can also be prepared on the thin film encapsulation layer 108. Exemplarily, as shown in FIG. 10, the color blocking structure array 122 may include red color blockers R′, green color blockers G′ and blue color blockers B′ arranged in an array. The multifunctional layer 102 may include red sub-pixels R, green sub-pixels G and blue sub-pixels B. The red color blockers R′ may be arranged correspondingly to the red sub-pixels R, the green color blockers G′ may be arranged correspondingly to the green sub-pixels G, and the blue color blockers B′ may be arranged correspondingly to the blue sub-pixels B. Further, the black matrix 121 may be disposed between adjacent color blocking structures. For example, the black matrix 121 may be arranged between the red color blockers R′ and the green color blockers G′, and between the green color blockers G′ and the blue color blockers B′.

In the present disclosure, the black matrix 121 may be disposed between adjacent color blocking structures. The black matrix 121 may extend to above the edge climbing position 12 of the organic encapsulation layer 104, and a portion of the black matrix 121 above the edge climbing position 12 may be used as the light shielding layer 113. For example, as shown in FIG. 10, the black matrix 121 may be disposed on the right of the blue color blockers B′, and the black matrix 121 may extend to above the edge climbing position 12 of the organic encapsulation layer 104.

In the present disclosure, the black matrix 121 may extend to above the edge climbing position 12 of the organic encapsulation layer 104, and the portion of the black matrix 121 above the edge climbing position 12 may be used as the light shielding layer 113. Therefore, the light shielding layer may be realized between the organic encapsulation layer 105 and the cover plate 107, blocking the light transmission path between the edge climbing position 112 of the organic encapsulation layer 104 and the cover plate 107. When the light from the display area is emitted to the edge climbing position 112, the black matrix 121 provided at the edge climbing position 112 may be used as a light shielding layer to block the light emitted from the display area to the edge climbing position 112.

In some embodiments, as shown in FIG. 2 to FIG. 10, the light shielding layer 113 may be a reflective layer.

By using the reflective layer disposed at the edge climbing position 112, the light emitted from the display area to the edge climbing position 112 may be reflected back, which improves the light leakage caused by the light from the display area when it is emitted to the edge area and also is conducive to improving the light utilization rate and the display effect of the display panel.

For example, as shown in the optical path schematic diagram of FIG. 2, when the light from the display area is emitted to the edge climbing position 112, the light may be reflected by the light shielding layer 113 (set as a reflective layer) to be reflected back, thereby avoiding light leakage from the edge area, which is conducive to improving the light utilization rate and the display effect of the display panel.

In some other embodiments, as shown in FIG. 2 to FIG. 10, the light shielding layer 113 may be a light absorbing layer.

The light absorbing layer may be a black coating, such as a black photoresist or a black paint. When the light from the display area is emitted to the edge climbing position 112 and passes through the light shielding layer 113, the light absorbing layer may absorb the light, thereby avoiding the problem of light leakage in the edge area to form an aperture.

In some other embodiments, the light shielding layer 113 may be set to a functional material layer well known to those skilled in the art, to block the light emitted from the display area to the edge climbing position, which is not specifically limited in the embodiments of the present disclosure.

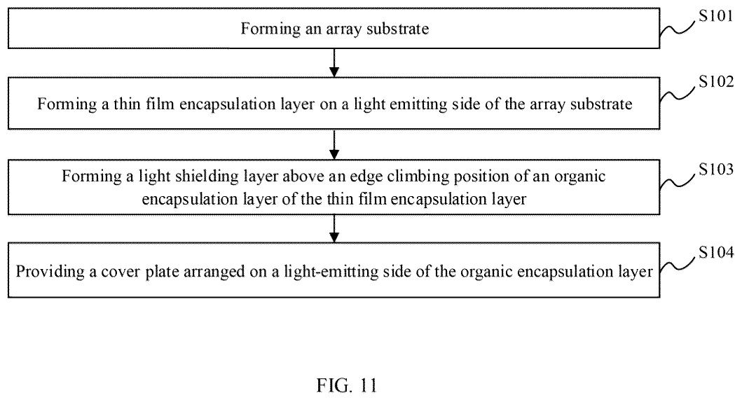

The present disclosure also provides a fabrication method of a display panel. As shown in FIG. 11, in one embodiment, the fabrication method of a display panel may include:
S101: forming an array substrate;
S102: forming a thin film encapsulation layer on a light-emitting side of the array substrate;
S103: forming a light shielding layer above an edge climbing position of an organic encapsulation layer of the thin film encapsulation layer; and
S104: providing a cover plate on a light-emitting side of the organic encapsulation layer.

As shown in FIG. 3, an array substrate 100 may be formed. The array substrate 100 may include a substrate 101 such as a flexible substrate 101 and a multifunctional layer 102 disposed on the substrate 101. The multifunctional layer 102 may include a driving circuit layer, an anode layer, an organic light-emitting layer, and a cathode layer, etc., which are stacked and are not limited or described in detail herein. The array substrate 100 may be formed by technical means well known to those skilled in the art, which are not described in detail herein.

After the array substrate 100 is prepared, a thin film encapsulation layer 108 may be formed on a light-emitting side of the array substrate 100. The thin film encapsulation layer 108 may include a first inorganic encapsulation layer 103, an organic encapsulation layer 104, and a second inorganic encapsulation layer 105.

A light shielding layer 113 may be then formed above an edge climbing position 112 of the organic encapsulation layer 105 of the thin film encapsulation layer 108, and a cover plate 107 may be disposed on the light-emitting side of the organic encapsulation layer 105. The cover plate 107 may be covered on the upper surface of the thin film encapsulation layer 108 by an adhesive layer 106.

Therefore, a display panel as shown in FIG. 3 may be formed by the fabrication method shown in FIG. 11 above, and the light shielding layer may be provided at a position between the organic encapsulation layer and the cover plate and corresponding to the edge climbing position of the organic encapsulation layer of the display panel. When the light from the display area is emitted to the edge climbing position, the light shielding layer provided at the edge climbing position of the organic encapsulation layer may block the light emitted from the display area to the edge climbing position, thereby improving the problem of light leakage caused by light from the display area being emitted to the edge area.

The present disclosure does not specifically limit the order of S102 and S103 in FIG. 11. For example, in some embodiments, after the organic encapsulation layer is formed on the light-emitting side of the array substrate, the light shielding layer may be formed on the surface of the edge climbing position of the organic encapsulation layer; or the light shielding layer may be formed on the surface of the edge climbing position of the thin film encapsulation layer.

In some embodiments, forming the light shielding layer above the edge climbing position of the organic encapsulation layer in the thin film encapsulation layer may include: forming the light shielding layer on the surface of the edge climbing position of the organic encapsulation layer.

As shown in FIG. 2, after the first inorganic encapsulation layer 103 and the organic encapsulation layer 104 are sequentially prepared on the light-emitting side of the array substrate 100, the light shielding layer 113 may be formed on the surface of the organic encapsulation layer 104, and the light shielding layer 113 may be located at the edge climbing position 112. And then the second inorganic encapsulation layer 105 may be formed. Thus, the light shielding layer 113 may be formed on the surface of the edge climbing position 112 of the organic encapsulation layer 104, and the light shielding layer 113 may be set between the organic encapsulation layer 104 and the cover plate 107, thereby blocking the light transmission path between the edge climbing position 112 of the organic encapsulation layer 104 and the cover plate 107.

In some other embodiments, forming the light shielding layer above the edge climbing position of the organic encapsulation layer of the thin film encapsulation layer may also include: forming the light shielding layer on the surface of the edge climbing position of the thin film encapsulation layer.

As shown in FIG. 3, after the first inorganic encapsulation layer 103, the organic encapsulation layer 104, and the second inorganic encapsulation layer 105 are sequentially prepared on the light-emitting side of the array substrate 100, the light shielding layer 113 may be formed on the surface of the second inorganic encapsulation layer 105 at the edge climbing position. The first inorganic encapsulation layer 103, the organic encapsulation layer 104, and the second inorganic encapsulation layer 105 may form the thin film encapsulation layer 108. That is, the light shielding layer 113 may be formed on the surface of the edge climbing position 112 of the thin film encapsulation layer 108.

Thus, the light shielding layer 113 may be formed on the surface of the edge climbing position 112 of the thin film encapsulation layer 108, and the light shielding layer 113 may be set between the organic encapsulation layer 104 and the cover plate 107, thereby blocking the light transmission path between the edge climbing position 112 of the organic encapsulation layer 104 and the cover plate 107.

During the encapsulation process of the thin film encapsulation layer 108, since the organic encapsulation layer 104 is in liquid state before solidification and has high fluidity, it may be difficult to accurately control diffusion of the organic encapsulation layer 104 and the organic encapsulation layer 104 is easy to flow out. Therefore, a first retaining wall structure 001 and a second retaining wall structure 002 may be set to prevent the organic encapsulation layer 104 from flowing out before solidification, which may ensure that the second inorganic encapsulation layer 105 effectively wraps the organic encapsulation layer 104 and prevent water and oxygen in the external environment from easily entering the interior of the display device to corrode the organic light-emitting layer and cause the problem of display black spots.

In one embodiment shown in FIG. 2, when forming the light shielding layer 113 of the display panel, the light shielding layer 113 may be set on the surface of the edge climbing position 112 of the organic encapsulation layer 104. In another embodiment shown in FIG. 3, when forming the light shielding layer 113, the light shielding layer 113 may be set on the surface of the edge climbing position 112 of the thin film encapsulation layer 108.

The display panel shown in FIG. 3 is a preferred embodiment of the embodiments of the present disclosure. After the thin film encapsulation layer 108 is formed, the light shielding layer 113 may be set on the surface of the edge climbing position 112 of the thin film encapsulation layer 108, which may not affect the preparation process of the thin film encapsulation layer 108. Please see the above for details and will not be repeated here.

In some embodiments, after the thin film encapsulation layer is formed on the light-emitting side of the array substrate, the fabrication method of the display panel may further include: forming a touch structure layer, and forming the light shielding layer at a position on the surface of any film layer of the touch structure layer away from the thin film encapsulation layer corresponding to the edge climbing position of the organic encapsulation layer.

As shown in FIG. 4 or FIG. 5, the display panel may be provided to include a touch structure layer 118, and the touch structure layer 118 may be located between the thin film encapsulation layer 108 and the cover plate 107. The light shielding layer 113 may be arranged at the edge climbing position 112 and located on the surface of any film layer of the touch structure layer 118 away from the thin film encapsulation layer 108.

After the thin film encapsulation layer 108 is formed on the array substrate 100, the touch structure layer 118 may be formed on the thin film encapsulation layer 108. The formed touch structure layer 118 may include multiple film layers. Exemplarily, as shown in FIG. 5 and FIG. 6, the touch structure layer 118 may include a first touch metal layer 114, a first insulating layer 115, a second touch metal layer 116, and a second insulating layer 117. When the light shielding layer 113 is formed, the light shielding layer 113 may be disposed at a position on a surface of any film layer of the touch structure layer 118 away from the thin film encapsulation layer 108 corresponding to the edge climbing position 112.

In some embodiments shown in FIG. 4 and FIG. 5, at a position corresponding to the edge climbing position 112, the touch structure layer 118 may include a first insulating layer 115 and a second insulating layer 117 stacked in sequence.

In one embodiment shown in FIG. 4, the light shielding layer 113 may be disposed on the surface of the first insulating layer 115 away from the thin film encapsulation layer 108. That is, the light shielding layer 113 may be disposed on the upper surface of the first insulating layer 115, and the light shielding layer 113 may be located at a position corresponding to the edge climbing position 112.

In another embodiment shown in FIG. 5, the light shielding layer 113 may be disposed on the surface of the second insulating layer 117 away from the thin film encapsulation layer 108. That is, the light shielding layer 113 may be disposed on the upper surface of the second insulating layer 117, and the light shielding layer 113 may be located at a position corresponding to the edge climbing position 112.

The embodiments of the present disclosure do not specifically limit this, and the light shielding layer 113 may be disposed on a surface of any film layer of the touch structure layer 118 away from the thin film encapsulation layer 108, and may be located at a position corresponding to the edge climbing position 112.

In some other embodiments, after the thin film encapsulation layer is formed on the light-emitting side of the array substrate, the method may further include: forming a touch structure layer; forming an opening at a position in an insulating layer of the touch structure layer corresponding to the edge climbing position of the thin film encapsulation layer; and forming the light shielding layer in the opening.

As shown in FIG. 6 or FIG. 7, after the thin film encapsulation layer 108 is formed on the light-emitting side of the array substrate 100, a touch structure layer 118 may be formed, that is, the touch structure layer 118 may be formed between the thin film encapsulation layer 108 and the cover plate 107. The touch structure layer 118 may include multiple film layers. The touch structure layer 118 shown in FIG. 6 and FIG. 7 may include a first touch metal layer 114, a first insulating layer 115, a second touch metal layer 116, and a second insulating layer 117. The light shielding layer 113 may be arranged on any film layer in the touch structure layer 118, such as the second insulating layer 117, which is away from the surface of the thin film encapsulation layer 108. That is, the light shielding layer 113 may be disposed on the upper surface of the second insulating layer 117, and the light shielding layer 113 may correspond to the edge climbing position 112. The position of the light shielding layer 113 may be understood as the position of the opening position.

The opening may be formed at a position of the insulating layer corresponding the edge climbing position 112 of the thin film encapsulation layer 108, and the light shielding layer 113 may be formed in the opening. When the light of the display area is emitted to the edge climbing position 112, the light emitted from the display area to the edge climbing position 112 may be blocked by the light shielding layer 113 arranged in the opening corresponding to the edge climbing position 112.

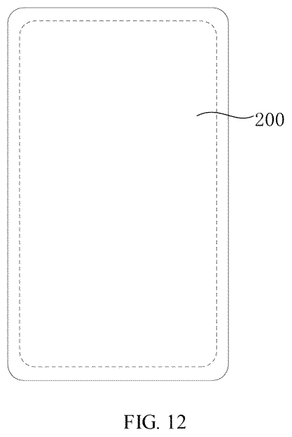

The present disclosure also provides a display device. As shown in FIG. 12 which is a schematic diagram of the structure of a display device provided by one embodiment of the present disclosure, the display device may include a display panel 200 provided by any embodiments of the present disclosure. The embodiment provided in FIG. 12 only takes a mobile phone as an example to illustrate the display device. It can be understood that the display device may be any electronic product with a display function, including but not limited to: mobile phones, televisions, laptops, desktop displays, tablet computers, digital cameras, smart bracelets, smart glasses, car displays, medical equipment, industrial control equipment, touch interactive terminals, etc., and the embodiment of the present disclosure does not specifically limit this.

The display device in the present disclosure may include a display panel provided by various embodiments of the present disclosure. Therefore, the display device may also alleviate the same technical problems as the above display panel embodiments and achieve the same technical effects, which will not be repeated here.

The modules or steps of the present disclosure described above can be implemented by a general-purpose computing device, they can be concentrated on a single computing device, or distributed on a network composed of multiple computing devices, they can be implemented by a program code executable by a computing device, so that they can be stored in a storage device and executed by the computing device, and in some cases, the steps shown or described can be executed in a different order from that here, or they can be made into individual integrated circuit modules, or multiple modules or steps therein can be made into a single integrated circuit module for implementation. In this way, the present disclosure is not limited to any specific combination of hardware and software.

It should be understood by those skilled in the art that the embodiments of the present disclosure can be provided as a method, system, or computer program product. Therefore, the present disclosure can take the form of a complete hardware embodiment, a complete software embodiment, or an embodiment combining software and hardware. Moreover, the present disclosure can take the form of a computer program product implemented on one or more computer-usable storage media (including but not limited to disk storage, CD-ROM, optical storage, etc.) containing computer-usable program codes.

The present disclosure is described with reference to the flowcharts and/or block diagrams of the methods, devices (systems), and computer program products according to the embodiments of the present disclosure. It should be understood that each process and/or box in the flowchart and/or block diagram, as well as the combination of processes and/or boxes in the flowchart and/or block diagram, can be implemented by computer program instructions. These computer program instructions can be provided to a processor of a general-purpose computer, a special-purpose computer, an embedded processor, or other programmable data processing device to produce a machine, so that the instructions executed by the processor of the computer or other programmable data processing device produce a device for implementing the functions specified in one or more processes in the flowchart and/or one or more boxes in the block diagram.

These computer program instructions can also be stored in a computer-readable memory that can guide a computer or other programmable data processing device to work in a specific manner, so that the instructions stored in the computer-readable memory produce a product including an instruction device, which implements the functions specified in one or more processes in the flowchart and/or one or more boxes in the block diagram.

These computer program instructions can also be loaded onto a computer or other programmable data processing device, so that a series of operating steps are performed on the computer or other programmable device to produce a computer-implemented process, so that the instructions executed on the computer or other programmable device provide steps for implementing the functions specified in one or more processes in the flowchart and/or one or more boxes in the block diagram.

In a typical configuration, a computing device includes one or more processors (CPU), input/output interfaces, network interfaces, and a memory. The memory may include non-permanent memory in a computer-readable medium, random access memory (RAM) and/or non-volatile memory in the form of read-only memory (ROM) or flash RAM. Memory is an example of a computer-readable medium. The computer-readable medium may include permanent and non-permanent, removable and non-removable media that can be implemented by any method or technology to store information. Information can be computer-readable instructions, data structures, modules of programs, or other data. Examples of computer storage media include, but are not limited to, phase change memory (PRAM), static random access memory (SRAM), dynamic random access memory (DRAM), other types of random access memory (RAM), read-only memory (ROM), electrically erasable programmable read-only memory (EEPROM), flash memory or other memory technology, compact disk read-only memory (CD-ROM), digital versatile disk (DVD) or other optical storage, magnetic cassettes, tape disk storage or other magnetic storage devices or any other non-transmission media that can be used to store information that can be accessed by a computing device. According to the definition in this article, computer-readable media does not include temporary computer-readable media (transitory media), such as modulated data signals and carrier waves.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising:
an array substrate;
a thin film encapsulation layer located on a light-emitting side of the array substrate, wherein the thin film encapsulation layer includes an organic encapsulation layer;
a cover plate located on a side of the thin film encapsulation layer away from the array substrate; and
a light shielding layer at an edge climbing position of the organic encapsulation layer, wherein the light shielding layer is disposed between the organic encapsulation layer and the cover plate.

2. The display panel according to claim 1, wherein:
the light shielding layer is located at the edge climbing position of an upper surface of the organic encapsulation layer.

3. The display panel according to claim 1, wherein:
the light shielding layer is located at the edge climbing position of a top layer of the thin film encapsulation layer.

4. The display panel according to claim 1, further including a touch structure layer between the thin film encapsulation layer and the cover plate, wherein:
the light shielding layer is located on a surface of any layer of the touch structure layer away from the thin film encapsulation layer.

5. The display panel according to claim 1, further including a touch structure layer between the thin film encapsulation layer and the cover plate, wherein:
the light shielding layer is located on a surface of the touch structure layer away from the thin film encapsulation layer.

6. The display panel according to claim 1, wherein:
a thickness of the light shielding layer is less than 30 microns.

7. The display panel according to claim 1, further including a touch structure layer between the thin film encapsulation layer and the cover plate, wherein:
the touch control structure layer includes an insulating layer;
the insulating layer is provided with an opening at the edge climbing position of the thin film encapsulation layer; and
the light shielding layer is located in the opening.

8. The display pane according to claim 7, wherein:
a side surface of the light shielding layer away from the thin film encapsulation layer is flush with a side surface of the touch structure layer away from the thin film encapsulation layer.

9. The display panel according to claim 1, further including a touch structure layer between the thin film encapsulation layer and the cover plate, wherein:
the light shielding layer is located at a side of the touch structure layer away from the cover plate; and
a groove structure is provided on the light shielding layer, and touch leads of the touch structure layer are located in the groove structure.

10. The display panel according to claim 1, further including a color blocking structure array between the thin film encapsulation layer and the cover plate, wherein:
a black matrix is arranged between adjacent color blocking structures of the color blocking structure array; and
the black matrix extends to the edge climbing position of the organic encapsulation layer to form the light shielding layer.

11. The display panel according to claim 1, wherein:
the light shielding layer includes a reflective layer.

12. The display panel according to claim 1, wherein:
the light shielding layer includes an absorption layer.

13. A fabrication method of a display panel, comprising:
forming an array substrate;
forming a thin film encapsulation layer on a light-emitting side of the array substrate;
forming a light shielding layer above an edge climbing position of an organic encapsulation layer of the thin film encapsulation layer; and
providing a cover plate arranged on a light-emitting side of the organic encapsulation layer.

14. The method according to claim 13, wherein forming the light shielding layer above the edge climbing position of the organic encapsulation layer of the thin film encapsulation layer includes:
forming the light shielding layer at the edge climbing position on a surface of the organic encapsulation layer.

15. The method according to claim 13, wherein forming the light shielding layer above the edge climbing position of the organic encapsulation layer of the thin film encapsulation layer includes:
forming the light shielding layer at the edge climbing position on a surface of the thin film encapsulation layer.

16. The method according to claim 13, after forming the thin film encapsulation layer on the light-emitting surface of the array substrate, further including:
forming a touch structure layer between the thin film encapsulation layer and the cover plate, wherein:
forming the light shielding layer above the edge climbing position of the organic encapsulation layer of the thin film encapsulation layer includes: forming the light shielding layer at a position on a surface of any layer of the touch structure layer away from the thin film encapsulation layer corresponding to the edge climbing position of the thin film encapsulation layer.

17. The method according to claim 13, after forming the thin film encapsulation layer on the light-emitting surface of the array substrate, further including:
forming a touch structure layer between the thin film encapsulation layer and the cover plate; and
forming an opening at a position of an insulating layer of the touch structure layer corresponding to the edge climbing position of the thin film encapsulation layer,
wherein:
forming the light shielding layer above the edge climbing position of the organic encapsulation layer of the thin film encapsulation layer includes forming the light shielding layer in the opening.

18. A display device, comprising a display panel, wherein:
the display panel includes:
an array substrate;
a thin film encapsulation layer located on a light-emitting side of the array substrate, wherein the thin film encapsulation layer includes an organic encapsulation layer;
a cover plate located on a side of the thin film encapsulation layer away from the array substrate; and
a light shielding layer at an edge climbing position of the organic encapsulation layer, wherein the light shielding layer is disposed between the organic encapsulation layer and the cover plate.
